(19) United States
(12) Patent Application Publication
(10) Pub. No.: US 2023/0175163 A1
(43) Pub. Date: Jun. 8, 2023

(54) SUBSTRATE HOLDER, PLATING APPARATUS AND METHOD FOR MANAGING SUBSTRATE HOLDER

(71) Applicant: EBARA CORPORATION, Tokyo (JP)

(72) Inventors: Masayuki FUJIKI, Tokyo (JP); Kei KITAMURA, Tokyo (JP)

(21) Appl. No.: 18/075,079

(22) Filed: Dec. 5, 2022

(30) Foreign Application Priority Data
Dec. 7, 2021 (JP) 2021-198699

(51) Int. Cl. C25D 17/06; C25D 21/12; G06K 19/07; G06K 7/10

(52) U.S. Cl. CPC C25D 17/06; C25D 21/12; G06K 19/0723; G06K 7/10366

(57) ABSTRACT

Provided is a technique for appropriately handling a substrate holder depending on a use state of the substrate holder. The substrate holder for holding a substrate that is a plating target in a plating apparatus is suggested. The substrate holder includes an RFID tag, and the RFID tag includes a storage region in which a use attribute is stored, the use attribute including an attribute indicating a state of being used for plating processing.

### TECHNICAL FIELD

The present application relates to a substrate holder, a plating apparatus, and a method for managing a substrate holder.

### BACKGROUND ART

Conventionally, an apparatus that performs electroplating by immersing a substrate into a plating solution is known, the substrate being held in a substrate holder, the plating solution being contained in a plating tank. In such a plating apparatus, the substrate holder is housed in a stocker for housing the substrate holder before an operation of the apparatus. The substrate holder is taken out from the stocker when the operation of the apparatus is started and holds a substrate such as a wafer to be processed. The substrate holder holding the substrate is transferred, by a substrate holder transfer machine, to the plating tank and each processing tank required for plating processing, and required processing is sequentially performed. In addition, the substrate holder in which poor power supply is found is returned to the stocker and its use is restricted until maintenance is completed.

### CITATION LIST

### Patent Literature

PTL 1: Japanese Patent Laid-Open No. 2017-190507
PTL 2: Japanese Patent Laid-Open No. 2014-19900
PTL 3: Japanese Patent Laid-Open No. 2018-53301

### SUMMARY OF INVENTION

### Technical Problem

In such a plating apparatus, in a case where a failure or the like occurs in the apparatus, a user may take out a substrate holder that is in a stocker or being processed to outside of the apparatus in order to solve the failure. Particularly, in this case of being taken out, a state of the substrate holder may be unknown, such as whether the substrate holder has been in an unused state or in a step of processing. If the substrate holder having been in the step of processing is used as a substrate holder in the unused state, there is concern that substrate contamination is caused and that the substrate holder cannot be appropriately maintained. Conventionally, it is left to management by an operator whether or not the substrate holder housed in the stocker is appropriately maintained and housed as the unused state. For this reason, if the appropriate management by the operator is not performed, the substrate holder that is not maintained may be used as the unused state.

One of objects of the present application is to provide a technique for appropriately handling the substrate holder depending on a use state of the substrate holder in view of the above actual situation.

### Solution to Problem

According to one embodiment, a substrate holder for holding a substrate that is a plating target in a plating apparatus is provided, and the substrate holder includes an RFID tag, and the RFID tag includes a storage region in which a use attribute is stored, the use attribute including an attribute indicating a state of being used for plating processing.

According to another embodiment, a method for managing a substrate holder for use in a plating apparatus is provided, and such a managing method includes a step of reading, in the plating apparatus, an RFID tag provided in the substrate holder, a step of determining, based on a use attribute stored in the RFID tag, whether or not to perform plating processing of a substrate by use of the substrate holder, and a step of updating the use attribute stored in the RFID tag for the substrate holder utilized in the plating processing.

### BRIEF DESCRIPTION OF DRAWINGS

FIG. 1 is an overall arrangement diagram of a plating apparatus according to one embodiment;

FIG. 2 is a diagram schematically showing a configuration of a substrate holder according to one embodiment;

FIG. 3 is a flowchart showing a process of using the substrate holder in the plating apparatus according to one embodiment;

FIG. 4 is a flowchart showing a maintenance process of the substrate holder by a terminal for maintenance according to one embodiment; and

FIG. 5 is a schematic configuration diagram of a plating system including a plurality of processing lanes according to a modification.

### DESCRIPTION OF EMBODIMENTS

Hereinafter, embodiments of a plating apparatus and a plating method according to the present invention will be described with reference to the drawings. In the drawings, the same or similar elements are denoted with the same or similar reference sign, and in the description of the respective embodiments, duplicate description of the same or similar elements may not be made. Further, characteristics shown in each embodiment are also applicable to another embodiment as long as the characteristics do not contradict each other.

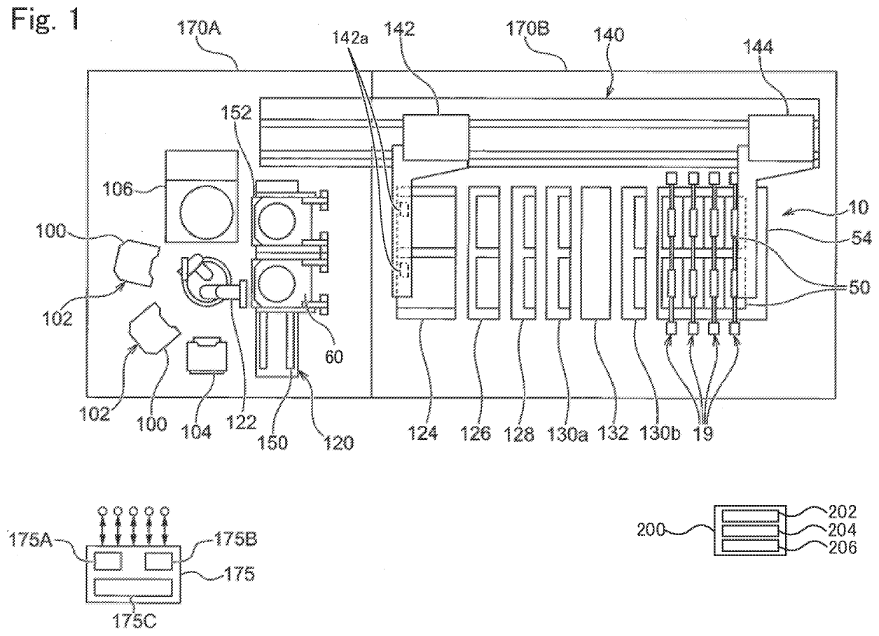

FIG. 1 is an overall arrangement diagram of a plating apparatus in an embodiment. In the present embodiment, a plating target is a substrate such as a semiconductor wafer. Examples of the substrate include a polygonal substrate such as a square or hexagonal substrate, and a circular substrate. As shown in FIG. 1, the plating apparatus is roughly divided into a load port 170A to load the substrate into a substrate holder 60 or unload the substrate from the substrate holder 60, and a processing unit 170B to process the substrate.

The load port 170A includes two cassette tables 102, an aligner 104, and a spin rinse dryer 106. On each cassette table 102, a cassette 100 that houses a substrate such as a semiconductor wafer is mounted. The aligner 104 is provided to align positions of an orientation flat, a notch and the like of the substrate in a predetermined direction. The spin rinse dryer 106 is provided to rotate, at a high speed, and dry the plated substrate. A substrate attaching/detaching mechanism 120 on which the substrate holder 60 is placed to attach and detach the substrate is provided near the spin rinse dryer 106. In a center of these units 100, 104, 106 and 120, a substrate transfer device 122 including a transfer robot for transferring the substrate between these units is disposed.

The substrate attaching/detaching mechanism 120 includes a flat plate-shaped placing plate 152 that can slide laterally along a rail 150. Two substrate holders 60 are horizontally placed in parallel on the placing plate 152. Then, after the substrate is delivered between one substrate holder 60 and the substrate transfer device 122, the placing plate 152 is slid laterally, and the substrate is delivered between the other substrate holder 60 and the substrate transfer device 122. The substrate attaching/detaching mechanism 120 may have functions as a leak detection device and a current measuring device for performing various inspections on the substrate holder 60.

The leak detection device is a device for inspecting leak from a sealed space of the substrate holder 60. In the substrate holder 60, as will be described later, when the substrate is held in the substrate holder 60, the surface of the substrate is sealed to form a space into which any plating solution does not enter. The substrate holder 60 includes, in this sealed space, a plurality of electrical contacts each of which comes in contact with the surface of the substrate to pass current through the substrate. If such a seal function decreases, the plating solution enters the electrical contacts in the substrate holder during the plating processing, and the current cannot appropriately flow through the substrate. Therefore, a seal performance of the substrate holder 60 is inspected in the leak detection device. As the leak detection device, any device including a known leak detection device may be used. The leak detection device can be configured to inspect the substrate holder for the leak before and after the plating processing. In addition, a plurality of leak detection devices may be provided, some of which may be used for the leak inspection before the plating processing, and some of which may be used for the leak inspection after the plating processing. For example, the leak detection device for the leak inspection before the plating processing may be a device that draws a vacuum from a sealed region of the substrate holder 60, to inspect whether a predetermined degree of vacuum can be maintained for a predetermined time. Further, the leak detection device for the leak inspection after the plating processing may be a device that inspects whether a liquid such as the plating solution adheres on the sealed region of the substrate holder 60.

The current measuring device is a device for measuring a current or resistance of each electrical contact in the substrate holder 60. In the substrate holder 60, a plurality of electrical contacts exist for uniformly passing current through the held substrate. If an abnormality occurs in one electrical contact and the electrical contact has a resistance larger or smaller than that of another electrical contact, current cannot be uniformly passed through the substrate, and normal plating processing cannot be performed. Therefore, in the current measuring device, the current or resistance flowing through the electrical contact of the substrate holder 60 is measured before the plating processing, to inspect whether an abnormality occurs in the electrical contact of the substrate holder 60. As the current measuring device, any device including a known current measuring device may be used.

The processing unit 170B of the plating apparatus includes a stocker 124, a prewet tank 126, a presoak tank 128, a first cleaning tank 130a, a blow tank 132, a second cleaning tank 130b, and plating tanks 50 in a plating module 10. In the stocker 124, the substrate holder 60 is kept and temporarily placed. In the prewet tank 126, the substrate is immersed in a prewet liquid such as pure water. In the presoak tank 128, an oxide film on the surface of a conductive layer such as a seed layer formed on the surface of the substrate is etched and removed. In the first cleaning tank 130a, the presoaked substrate is cleaned with a cleaning solution (pure water or the like) together with the substrate holder 60. In the blow tank 132, liquid draining of the cleaned substrate is performed. In the second cleaning tank 130b, the plated substrate is cleaned with the cleaning solution together with the substrate holder 60. The stocker 124, the prewet tank 126, the presoak tank 128, the first cleaning tank 130a, the blow tank 132, the second cleaning tank 130b and the plating tank 50 are arranged in this order as an example.

The plating module 10 includes, for example, a plurality of plating tanks 50 provided with an overflow tank 54. In each plating tank 50, one substrate is housed, and the substrate is immersed in the plating solution held inside, to perform plating such as copper plating on the surface of the substrate.

The plating apparatus includes a substrate holder transfer module 140 adopting, for example, a linear motor system that is located on a side of each unit of equipment and that transfers the substrate holder 60 together with the substrate between respective units of equipment. The substrate holder transfer module 140 includes a first transporter 142 and a second transporter 144. The first transporter 142 is configured to transfer the substrate to and from the substrate attaching/detaching mechanism 120, the stocker 124, the prewet tank 126, the presoak tank 128, the first cleaning tank 130a, and the blow tank 132. The second transporter 144 is configured to transfer the substrate to and from the first cleaning tank 130a, the second cleaning tank 130b, the blow tank 132, and the plating tank 50. In another embodiment, the plating apparatus may include only one of the first transporter 142 and the second transporter 144.

On opposite sides of the overflow tank 54, paddle drive devices 19 for driving paddles (not shown) as stirring rods located in the respective plating tanks 50 to stir the plating solution in the plating tanks 50 are arranged, respectively.

The plating apparatus includes a controller 175 as an example of a controller configured to control each part described above. The controller 175 includes a memory 175B in which a predetermined program is stored, a central processing unit (CPU) 175A that executes the program in the memory 175B, and a control unit 175C realized by the CPU 175A executing the program. For example, the control unit 175C can perform transfer control of the substrate transfer device 122, transfer control of the substrate holder transfer module 140, control of a plating current and plating time in the plating module 10, and the like. The controller 175 can be configured from, for example, a general purpose computer or a dedicated computer including an input/output device, a display device, a storage device and others, and in the computer, a program for controlling an operation of the plating apparatus is installed. Further, as an example, the controller 175 is configured to be able to communicate with an unshown host controller that generally controls the plating apparatus and other related devices and can exchange data with a database owned by the host controller.

In the present embodiment, a terminal for maintenance 200 for maintaining the plating apparatus is provided. The terminal for maintenance 200 may be configured from, for example, a general purpose computer or a dedicated computer including an input/output device, a display device, a storage device and others, and in the computer, a program for maintenance is installed. The terminal for maintenance 200 includes a memory 204 in which a predetermined program is stored, a CPU 202 that executes the program in the memory 204, and a control unit 206 realized by the CPU 202 executing the program. The terminal for maintenance 200 and the controller 175 are configured to be connectable in a wired or wireless manner. The control unit 206 can perform, for example, a maintenance operation such as resetting or backing up the controller 175 of the plating apparatus. The terminal for maintenance 200 has an RFID reader/writer function of reading and writing information stored in an after-mentioned RFID tag 62 of the substrate holder 60 and is configured to be able to perform maintenance of the substrate holder 60.

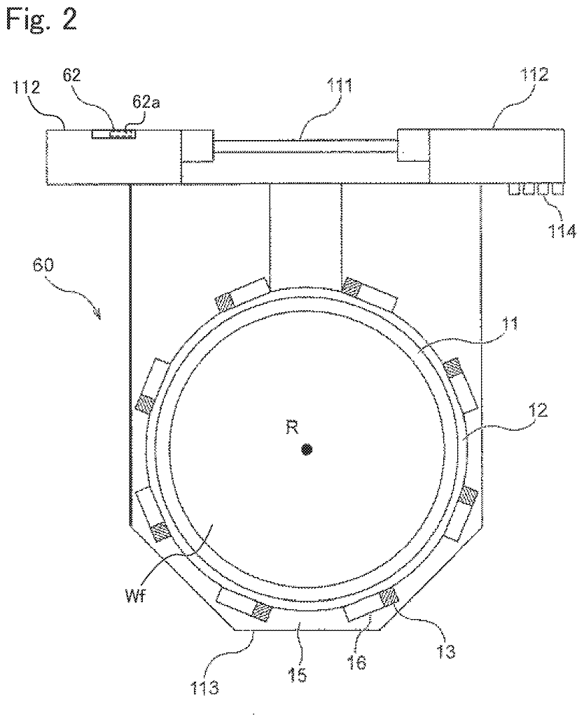

FIG. 2 is a schematic diagram showing a configuration of a substrate holder 60 that can be used in the plating apparatus according to the embodiment of the present invention. The substrate holder 60 of the present embodiment has one end provided with a handlebar 111. The handlebar 111 is held with the substrate holder transfer module 140. The handlebar 111 has a round bar shape so that the substrate holder 60 is rotatable when converting a posture from a vertical state to a horizontal state or from the horizontal state to the vertical state.

It is desirable that the handlebar 111 is made of stainless steel that is resistant to corrosion in preparation for a situation where the plating solution adheres. Additionally, in a case where stainless steel cannot withstand the corrosion due to the plating solution, it is recommended to improve corrosion resistance by chrome plating, TiC coating or the like of the surface of stainless steel. In addition, titanium having high corrosion resistance can be used for the handlebar 111.

Further, hanger portions 112 each having a rectangular parallelepiped shape or a cube shape are provided at opposite ends of an upper part of the substrate holder 60, respectively. Each hanger portion 112 functions as a support portion for suspending the substrate holder 60, when the substrate holder 60 is disposed on a hanger receiving member (not shown) in each processing tank. In the stocker 124 shown in FIG. 1, the substrate holder 60 is suspended vertically and supported by hooking the hanger portions 112 to an upper surface of a peripheral wall of the stocker 124. Further, the hanger portions 112 of the suspended supported substrate holder 60 are gripped with the first transporter 142 or the second transporter 144 to transfer the substrate holder 60. Also, in the prewet tank 126, the presoak tank 128, the cleaning tanks 130a and 130b, the blow tank 132 and the plating tanks 50, the substrate holder 60 is suspended and supported on peripheral walls of the tanks via the hanger portions 112. The hanger portions 112 are provided with external contacts 114 for connecting to an external power supply unit. Each external contact 114 is electrically connected to an electrical contact (not shown) for supplying current to a substrate Wf via a plurality of wirings inside the substrate holder 60. A plurality of electrical contacts of the substrate holder 60 are arranged outside a circumference of the substrate Wf so that an end portion of each electrical contact comes in contact with the surface of the substrate Wf when the substrate Wf is held in the substrate holder 60. In addition, a conductive layer (seed layer) is formed on the surface of the substrate Wf, and when the substrate Wf is held in the substrate holder 60, the electrical contacts come in contact with the conductive film on the surface of the substrate Wf, so that current can flow through the substrate Wf. Contact between the external contact 114 provided in the hanger portion 112 and the electrical contact of the hanger receiving member can supply current from an external power supply to the plated surface of the substrate Wf via a plurality of electrical contacts of the substrate holder 60. The external contact 114 is provided at a location where the substrate holder 60 suspended from the hanger receiving member does not come in contact with the plating solution in the plating tank.

The substrate holder 60 includes a movable holding member 11 that is a lid portion, and a fixed holding member 15 that is placed on the placing plate 152 of the substrate attaching/detaching mechanism 120. The substrate Wf is sandwiched between the movable holding member 11 and the fixed holding member 15 (FIG. 2 shows a sandwiched state). The movable holding member 11 is substantially annular and includes a pressing member 12, and an ear portion 13 that protrudes integrally with the pressing member 12 on an outer periphery. The movable holding member 11 can be fixed to the fixed holding member 15 and is removable from the fixed holding member 15. The fixed holding member 15 includes a damper 16 at a location corresponding to the ear portion 13. The damper 16 has an inverted L-shape with a tip being bent inward, and the ear portion 13 enters (fits) inside a tip bent portion, so that the movable holding member 11 can be fixed to the fixed holding member 15. It is desirable that the ear portion 13 and the damper 16 have a tapered portion for smooth fitting.

The pressing member 12 is held to be rotatable and not to be detached relative to the movable holding member 11 and rotates together with the ear portion 13 with a center R of the movable holding member 11 as a rotation center and with a substantially horizontal plane as a plane of rotation. The pressing member 12 is, for example, substantially annular.

The movable holding member 11 and the fixed holding member 15 sandwich the substrate therebetween, and the pressing member 12 is rotated to fit the ear portion 13 into the damper 16, thereby fixing the substrate Wf. Further, in a case of attaching and removing the substrate, the pressing member 12 is rotated to release the fitting between the ear portion 13 and the damper 16. The movable holding member 11 includes a seal ring for sealing, from the plating solution, a portion that need not be plated, such as an end portion or a back surface of the substrate Wf, and an electrical contact that comes in contact with an end region of the sealed substrate Wf to energize the substrate Wf (not shown).

The substrate holder 60 includes the RFID tag 62. As an example, the RFID tag 62 is attached to the hanger portion 112 in the fixed holding member 15 and may be attached to any position of the substrate holder 60. The RFID tag 62 can hold various pieces of information. As an example, the RFID tag 62 can hold specific information and maintenance history of the substrate holder, such as the date of manufacture of the substrate holder 60, a management number of the substrate holder (such as an ID of the substrate holder), information on the plating apparatus (such as an ID of the plating apparatus), the number of stockers on each of which the substrate holder is to be disposed, a cleaning date, the total number of times of cleaning from when the substrate holder is manufactured, the number of times of cleaning from when the substrate holder is thrown into the plating apparatus, an integrated current value through the electrical contacts of the substrate holder, the number of times of no good (NG) given by the current measuring device or leak detection device in the substrate attaching/detaching mechanism 120, a maintenance date, and a replacement date of components such as the seal ring and the electrical contact. In the present embodiment, the RFID tag 62 has a storage region 62a for storing “a use attribute”. As an example, the storage region 62a may be configured by a virtual logical volume in the RFID tag 62. The “use attribute” is information indicating a current use state of the substrate holder 60 and includes at least an attribute indicating a state where the substrate holder 60 is currently used for plating processing. The use attribute may include a state where the substrate holder 60 is under maintenance or a state where the substrate holder 60 is waiting for maintenance. The use attribute may include an attribute indicating a state where the substrate holder 60 is usable for plating processing. Here, examples of the state where the substrate holder 60 is usable for plating processing may include a state where the substrate holder 60 is not used, a state where the substrate holder 60 is maintained, and the like. In the present embodiment, “maintenance” includes cleaning. Alternatively, “the use attribute” may include a state related to the cleaning such as “a state of being waiting for cleaning” separately from “maintenance”. Further, it is preferable that “the use attribute” is stored together with time information when the use attribute is updated.

In the present embodiment, the transporter 142 for transferring the substrate holder 60 includes an RFID reader 142a configured to read information stored in the RFID tag 62 of the substrate holder 60 (see FIG. 1). The RFID reader 142a is controlled by the controller 175. Without being limited to such examples, the RFID reader may be provided in the substrate attaching/detaching mechanism 120 or the transporter 144 in place of or in addition to the transporter 142. In the present embodiment, the RFID reader 142a has a function as a writer capable of updating the information stored in the RFID tag 62 of the substrate holder 60. However, without being limited to such examples, in place of or in addition to the RFID reader 142a, a configuration having a function of an RFID writer may be provided in the substrate attaching/detaching mechanism 120 or the transporter 144.

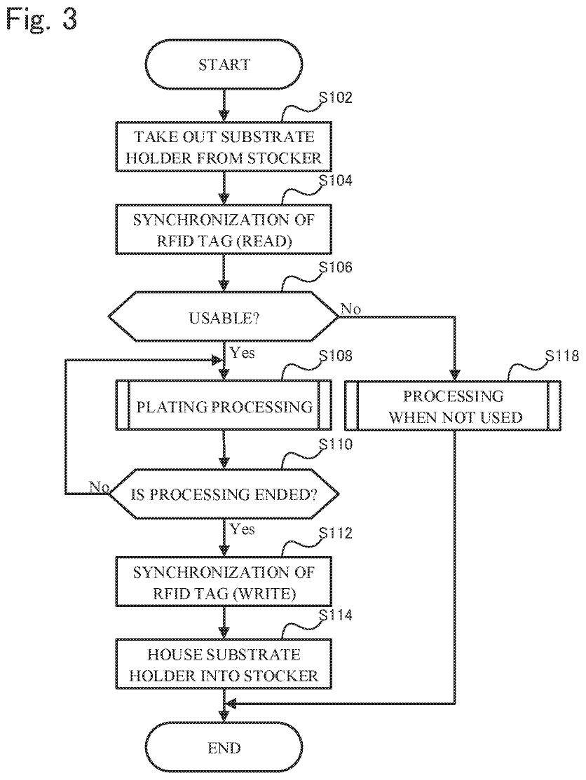

FIG. 3 is a flowchart showing a process of using the substrate holder in the plating apparatus according to one embodiment. The controller 175 executes this flowchart when a specific substrate holder 60 is used in performing the plating processing on the substrate Wf. In the preset process, first, the substrate holder 60 is taken out from the stocker 124 in order to use the specific substrate holder 60 (S102). Specifically, a command from the controller 175 controls the first transporter 142 to take out the specific substrate holder 60 from the stocker 124. At this time, the RFID reader 142a of the first transporter 142 reads the information stored in the RFID tag 62 of the substrate holder 60 (S104). The information read by the RFID reader 142a includes the use attribute of the substrate holder 60.

Then, the controller 175 determines, based on the information read from the RFID tag 62, whether or not the substrate holder 60 may be used for plating processing (S106). In processing of S106, in particular, the controller 175 determines, based on the use attribute of the substrate holder 60, whether or not the substrate holder 60 may be used. As an example, in a case where the use attribute of the substrate holder 60 indicates “the state of being usable for plating processing”, it is determined that the substrate holder 60 may be used. Further, in a case where the use attribute of the substrate holder 60 indicates “the state of being under maintenance” or “the state of being waiting for maintenance”, it is determined that the substrate holder 60 is to be maintained, and the substrate holder 60 is determined to be unusable. Further, in a case where the use attribute of the substrate holder 60 indicates “the state of being currently used for plating processing”, it is determined that the previous plating processing of the substrate holder 60 is not appropriately ended, and the substrate holder 60 is determined to be unusable. Furthermore, in the processing of S106, the controller 175 may determine whether or not the substrate holder 60 may be used for plating processing, based on other information read from the RFID tag 62 in addition to the use attribute of the substrate holder 60. As an example, the controller 175 may determine that the substrate holder 60 cannot be used, based on the specific information and maintenance history of the substrate holder that are stored in the RFID tag 62, even in a case where the use attribute of the substrate holder 60 indicates “the state being usable for plating processing”.

When it is determined that the substrate holder 60 may be used based on the information stored in the RFID tag 62 (S106: Yes), the plating processing is executed using the substrate holder 60 (S108). At this time, the RFID reader 142a may update the use attribute stored in the RFID tag 62 to information indicating “the state of being currently used for plating processing”. Note that when an abnormality (NG) is detected by the leak detection device or the current measuring device in the substrate attaching/detaching mechanism 120 with respect to the substrate holder 60 for use, the controller 175 may determine that the substrate holder 60 is cleaned to use the substrate holder 60 for plating processing. Further, in a case where an abnormality is detected in the substrate holder 60 in the substrate attaching/detaching mechanism 120, the controller 175 may update the use attribute stored in the RFID tag 62 to information indicating “the state of being waiting for maintenance” and return the substrate holder 60 to the stocker 124.

When the plating processing is started using the substrate holder 60, the controller 175 stores information on a utilization state of the substrate holder 60, such as the integrated current value through the electrical contact of the substrate holder 60 and the number of times of NG in the substrate attaching/detaching mechanism 120, until the plating processing ends (S110). Then, when the plating processing ends (S110: Yes), the controller 175 updates the information stored in the RFID tag 62 based on the information on the utilization state of the substrate holder 60 that is stored during the plating processing (S112). Thereby, the specific information of the substrate holder 60 stored in the RFID tag 62 is updated. At this time, the use attribute of the substrate holder 60 stored in the RFID tag 62 may be updated to information indicating “the state of being waiting for maintenance” or “the state of being usable for plating processing”. Then, the controller 175 returns the substrate holder 60 to the stocker 124 (S114) and ends the use of the substrate holder 60.

When the controller 175 determines that the substrate holder 60 cannot be used based on the information stored in the RFID tag 62 (S106: No), the plating processing is not performed using the substrate holder 60, and processing when the substrate holder is not used is executed (S118). This processing when the substrate holder is not used includes returning the substrate holder 60 as it is to the stocker 124. In the processing when the substrate holder is not used, different processing may be performed based on the use attribute stored in the RFID tag 62. As an example, when the substrate holder 60 is under maintenance or waiting for maintenance, the substrate holder 60 may be subjected to predetermined maintenance processing. As an example, in a case where the substrate holder 60 taken out from the stocker 124 is in “the state of being currently used for plating processing”, the substrate holder 60 is returned as it is to the stocker 124, and it may be notified by a lamp, buzzer, indicator, or the like that the substrate holder 60 has an abnormality. Further, as the processing when the substrate holder is not used, the substrate holder 60 may be taken out from the plating apparatus. In this case, an unshown swap station provided in the plating apparatus may be utilized. Then, on subjecting the substrate holder 60 to the processing when the substrate holder is not used, the controller 175 ends the use process shown in FIG. 3.

According to this use process of the substrate holder, “the use attribute” is stored in the RFID tag 62 of the substrate holder 60. Then, the controller 175 of the plating apparatus determines whether or not to perform plating processing of the substrate Wf by use of the substrate holder 60 based on “the use attribute” stored in the RFID tag. Thereby, the substrate holder can be handled appropriately depending on the use state of the substrate holder.

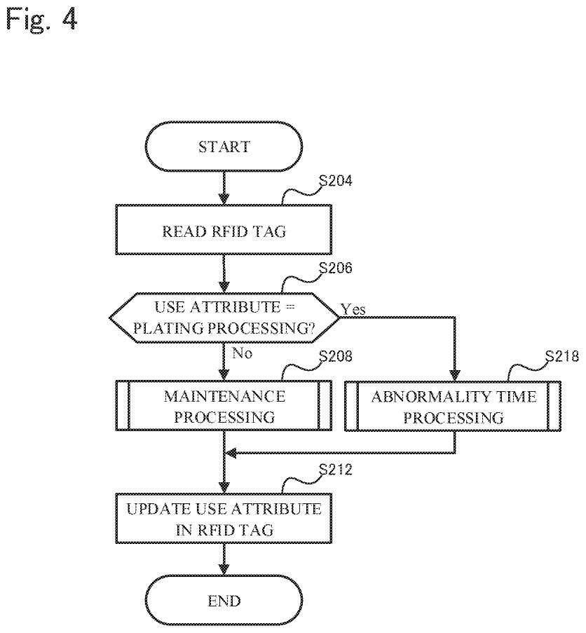

Next, the maintenance of the substrate holder 60 by use of the terminal for maintenance will be described. FIG. 4 is a flowchart showing a maintenance process according to one embodiment. As an example, this processing is performed by an operator taking out the substrate holder 60 from the stocker 124 and connecting the substrate holder 60 and the terminal for maintenance 200. As another example, the processing shown in FIG. 4 is performed in the unshown swap station by taking out the substrate holder 60 from the plating apparatus and transferring the substrate holder to a predetermined maintenance location.

In the maintenance process of the substrate holder 60 by the terminal for maintenance 200, first, the terminal for maintenance 200 reads the RFID tag 62 of the substrate holder 60 (S204). Subsequently, the terminal for maintenance 200 determines whether or not the use attribute stored in the RFID tag 62 indicates “the state of being currently used for plating processing” (S206). Then, when “the use attribute” does not indicate “the state of being currently used for plating processing” (S206: No), normal maintenance processing by use of the terminal for maintenance 200 is executed (S208). In processing of S208, as an example, components such as the seal ring and the electrical contact of the substrate holder 60 are replaced, and the specific information and maintenance history of the substrate holder that are stored in the RFID tag 62 are updated. Then, when the terminal for maintenance 200 ends maintenance processing of the substrate holder 60, the use attribute in the RFID tag 62 is updated to information indicating “the state of being usable for plating processing” (S212), thereby ending the maintenance process. The substrate holder 60 that ends the maintenance process is returned to the stocker 124 and is used again for plating processing in the plating apparatus.

When the use attribute stored in the RFID tag 62 indicates “the state of being currently used for plating processing” (S206: Yes), the terminal for maintenance 200 determines that abnormal processing is performed in the plating processing in which the substrate holder 60 is used and executes abnormality time processing (S218). In this abnormality time processing, as an example, the terminal for maintenance 200 may communicate with the controller 175 of the plating apparatus, to find out the cause. Particular, in a case where time information when the use attribute is updated to “the state of being currently used for plating processing” is stored in the RFID tag 62, the cause can be found out based on the time information. In the abnormality time processing, leak may be detected or abnormality of the electrical contact may be determined for the substrate holder 60. Further, in the abnormality time processing, the substrate holder 60 may be cleaned. Then, on ending the abnormality time processing, the terminal for maintenance 200 updates the use attribute of the RFID tag 62 depending on the result of the abnormality time processing (S212) and ends the maintenance process. As an example, in a case where the terminal for maintenance 200 determines that the substrate holder 60 may be used for plating processing in the abnormality time processing, the use attribute in the RFID tag 62 may be updated to the information indicating “the state of being usable for plating processing”. In this case, the substrate holder 60 is returned to the stocker 124 and is accordingly used again for plating processing in the plating apparatus.

<Modification>

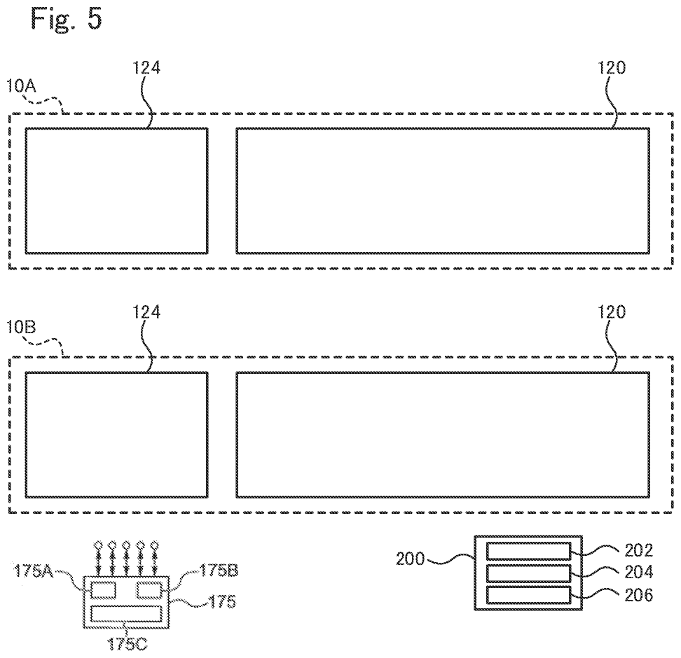

FIG. 5 is a schematic configuration diagram of a plating system including a plurality of processing lanes according to a modification. The plating system shown in FIG. 5 includes a first processing lane 10A and a second processing lane 10B. The plating system may include three or more processing lanes. In the present modification, each of the first and second processing lanes 10A and 10B corresponds to the processing unit 170B in the above described embodiment. The plating system includes a configuration corresponding to the controller 175 in the above plating apparatus and the terminal for maintenance 200. The same configuration as described in the above embodiment is denoted with the same reference signs, and duplicate description is not made.

In the present modification, “the use attribute” stored in the RFID tag 62 of the substrate holder 60 includes information for individually identifying the lane (device) in which the substrate holder 60 is currently placed. Specifically, the use attribute includes information as an example indicating “a state of being used in the first processing lane” and “a state of being used in the second processing lane”. In the present modification, the use attribute includes information indicating “an unused state” where the substrate holder is not used in either of the first and second processing lanes 10A and 10B, and “a maintenance waiting state” that requires maintenance outside the first and second processing lanes 10A and 10B.

The controller 175 for the plating system in the present modification determines permission/prohibition of use of the substrate holder 60 at a use destination based on the use attribute stored in the RFID tag 62 of the substrate holder 60. As an example, in a case where the use attribute of the substrate holder 60 indicates “the state of being used in the first processing lane”, the controller 175 permits the substrate holder 60 to be used in the first processing lane 10A and prohibits the substrate holder from being used in the second processing lane 10B. Further, in a case where the use attribute of the substrate holder 60 indicates “the state of being used in the second processing lane”, the controller 175 prohibits the substrate holder 60 from being used in the first processing lane 10A and permits the substrate holder to be used in the second processing lane 10B. Further, in a case where the use attribute of the substrate holder 60 indicates “the unused state”, the controller 175 permits the substrate holder to be used in both of the first and second processing lanes 10A and 10B. Further, in a case where the use attribute of the substrate holder 60 indicates “the maintenance waiting state”, the controller 175 prohibits the substrate holder from being used in either the first or second processing lane 10A, 10B.

According to the modification described above, the plating system includes a plurality of processing lanes in each of which the substrate holder 60 is used, and the processing lane in which the substrate holder 60 is usable is determined based on the use attribute stored in the RFID tag 62 of the substrate holder 60. Thereby, the substrate holder used in different processing lanes can be prevented from being used in unintended processing lanes. For example, in a case where a processing solution that differs with the processing lane is used, different processing solutions can be prevented from being mixed. Therefore, according to the plating system of the modification, the substrate holder 60 can be appropriately handled depending on the use state.

The present invention can be described in forms as follows.

[Form 1] According to Form 1, a substrate holder for holding a substrate that is a plating target in a plating apparatus is provided, and the substrate holder includes an RFID tag, and the RFID tag includes a storage region in which a use attribute is stored, the use attribute including an attribute indicating a state of being used for plating processing. According to Form 1, the substrate holder can be appropriately handled based on the use attribute stored in the RFID tag.

[Form 2] According to Form 2, in Form 1, the use attribute stored in the storage region includes a state where the substrate holder is under maintenance or a state where the substrate holder is waiting for maintenance. According to Form 2, based on the use attribute stored in the RFID tag, the state where the substrate holder is under maintenance or the state where the substrate holder is waiting for maintenance can be grasped.

[Form 3] According to Form 3, in Form 1 or 2, the use attribute stored in the storage region includes information for individually identifying a device in which the substrate holder is currently placed. According to Form 3, the device in which the substrate holder is currently placed can be grasped by reading the RFID tag.

[Form 4] According to Form 4, in Forms 1 to 3, the use attribute stored in the storage region includes time information when the use attribute is updated. According to Form 4, time when the use attribute stored in the RFID tag is updated can be grasped.

[Form 5] According to Form 5, in Forms 1 to 4, in the RFID tag, information indicating the number of times of use or a time of use for each component constituting the substrate holder is held. According to Form 5, the number of times of use or the time of use of the substrate holder can be managed based on the state stored in the RFID tag.

[Form 6] According to Form 6, a plating apparatus including a plating tank is provided, and the plating apparatus includes the substrate holder of Forms 1 to 5, a transfer module that transfers the substrate holder, an RFID reader configured to read information stored in the RFID tag of the substrate holder, and a controller that determines whether or not to perform plating processing of the substrate by use of the substrate holder, based on the use attribute of the substrate holder that is read by the RFID reader. According to Form 6, effects similar to those of Forms 1 to 5 can be exhibited.

[Form 7] According to Form 7, in Form 6, the plating apparatus includes a first processing lane and a second processing lane, a use attribute stored in the storage region of the substrate holder includes attributes indicating “an unused state”, “a state of being used in the first processing lane”, “a state of being used in the second processing lane”, and “a maintenance waiting state”, and the controller permits the substrate holder having the use attribute indicating “the unused state” to be used in the first processing lane or the second processing lane, permits the substrate holder having the use attribute indicating “the state of being used in the first processing lane” to be used in the first processing lane, permits the substrate holder having the use attribute indicating “the state of being used in the second processing lane” to be used in the second processing lane, and prohibits the substrate holder having the use attribute indicating “the maintenance waiting state” from being used in the first processing lane and the second processing lane. According to Form 7, the substrate holder can be appropriately handled depending on the use state of the substrate holder.

[Form 8] According to Form 8, in Form 6 or 7, the RFID reader is provided in the transfer module.

[Form 9] According to Form 9, in Forms 6 to 8, the RFID reader can update the information stored in the RFID tag.

[Form 10] According to Form 10, in Form 9, the RFID reader reads the use attribute stored in the RFID tag at a timing when use of the substrate holder is started, the controller stores a utilization state of the substrate holder in the plating processing, and the RFID reader updates the use attribute stored in the RFID tag based on the utilization state of the substrate holder that is stored by the controller at a timing when the use of the substrate holder is ended.

[Form 11] According to Form 11, a method for managing a substrate holder for use in a plating apparatus is provided, and such a managing method includes a step of reading, in the plating apparatus, an RFID tag provided in the substrate holder, a step of determining, based on a use attribute stored in the RFID tag, whether or not to perform plating processing of a substrate by use of the substrate holder, and a step of updating the use attribute stored in the RFID tag for the substrate holder utilized in the plating processing. According to Form 11, the substrate holder can be appropriately handled based on the use attribute stored in the RFID tag.

[Form 12] According to Form 12, in Form 11, the reading step is a step performed at a timing to start the use of the substrate holder, and the updating step is a step performed at a timing to end the use of the substrate holder.

[Form 13] According to Form 13, in Form 11 or 12, the plating apparatus includes a first processing lane and a second processing lane, the use attribute includes attributes indicating “an unused state”, “a state of being used in the first processing lane”, “a state of being used in the second processing lane”, and “a maintenance waiting state”, and the managing method includes permitting the substrate holder having the use attribute indicating “the unused state” to be used in the first processing lane or the second processing lane, permitting the substrate holder having the use attribute indicating “the state of being used in the first processing lane” to be used in the first processing lane, permitting the substrate holder having the use attribute indicating “the state of being used in the second processing lane” to be used in the second processing lane, and prohibits the substrate holder having the use attribute indicating “the maintenance waiting state” from being used in the first processing lane and the second processing lane. According to Form 13, the substrate holder can be appropriately handled depending on the use state of the substrate holder.

As above, the embodiments of the present invention have been described, and the above embodiments of the invention are intended to facilitate the understanding of the present invention and do not limit the present invention. Needless to say, the present invention can be modified and improved without departing from the spirit, and the present invention includes equivalents. Additionally, in a range in which at least some of the above-described problems can be solved or at least some of the effects can be exhibited, any combination of embodiments and modifications is possible, and any combination or omission of the respective components described in the claims and specification is possible.

This application claims priority based on Japanese Patent Application No. 2021-198699 filed on Dec. 7, 2021. All disclosed contents including the description, claims, drawings and abstract of Japanese Patent Application No. 2021-198699 are entirely incorporated herein by reference. All disclosures including the descriptions, claims, drawings and abstracts of Japanese Patent Laid-Open Nos. 2017-190507 (Patent Literature 1), 2014-19900 (Patent Literature 2), and 2018-53301 (Patent Literature 3) are entirely incorporated herein by reference.

### REFERENCE SIGNS LIST

10A, 10B processing lane
50 plating tank
60 substrate holder
62 RFID tag
62a storage region
120 substrate attaching/detaching mechanism
122 substrate transfer device
124 stocker
140 substrate holder transfer module
142 first transporter
142a RFID reader
175 controller
200 terminal for maintenance

What is claimed is:

1. A substrate holder for holding a substrate that is a plating target in a plating apparatus, comprising:
an RFID tag,
the RFID tag including a storage region in which a use attribute is stored, the use attribute including an attribute indicating a state of being used for plating processing.

2. The substrate holder according to claim 1, wherein the use attribute stored in the storage region includes a state where the substrate holder is under maintenance or a state where the substrate holder is waiting for maintenance.

3. The substrate holder according to claim 1, wherein the use attribute stored in the storage region includes information for individually identifying a device in which the substrate holder is currently placed.

4. The substrate holder according to claim 1, wherein the use attribute stored in the storage region includes time information when the use attribute is updated.

5. The substrate holder according to claim 1, wherein in the RFID tag, information indicating the number of times of use or a time of use for each component constituting the substrate holder is held.

6. A plating apparatus including a plating tank, comprising:
the substrate holder according to claim 1,
a transfer module that transfers the substrate holder,
an RFID reader configured to read information stored in the RFID tag of the substrate holder, and
a controller that determines whether or not to perform plating processing of the substrate by use of the substrate holder, based on the use attribute of the substrate holder that is read by the RFID reader.

7. The plating apparatus according to claim 6, comprising a first processing lane and a second processing lane, wherein a use attribute stored in the storage region of the substrate holder includes attributes indicating “an unused state”, “a state of being used in the first processing lane”, “a state of being used in the second processing lane”, and “a maintenance waiting state”, and
the controller permits the substrate holder having the use attribute indicating “the unused state” to be used in the first processing lane or the second processing lane, permits the substrate holder having the use attribute indicating “the state of being used in the first processing lane” to be used in the first processing lane, permits the substrate holder having the use attribute indicating “the state of being used in the second processing lane” to be used in the second processing lane, and prohibits the substrate holder having the use attribute indicating “the maintenance waiting state” from being used in the first processing lane and the second processing lane.

8. The plating apparatus according to claim 6, wherein the RFID reader is provided in the transfer module.

9. The plating apparatus according to claim 6, wherein the RFID reader updates the information stored in the RFID tag.

10. The plating apparatus according to claim 9, wherein the RFID reader reads the use attribute stored in the RFID tag at a timing when use of the substrate holder is started,
the controller stores a utilization state of the substrate holder in the plating processing, and
the RFID reader updates the use attribute stored in the RFID tag based on the utilization state of the substrate holder that is stored by the controller at a timing when the use of the substrate holder is ended.

11. A method for managing a substrate holder for use in a plating apparatus, comprising:
a step of reading, in the plating apparatus, an RFID tag provided in the substrate holder,
a step of determining, based on a use attribute stored in the RFID tag, whether or not to perform plating processing of a substrate by use of the substrate holder, and
a step of updating the use attribute stored in the RFID tag for the substrate holder utilized in the plating processing.

12. The managing method according to claim 11, wherein the reading step is a step performed at a timing to start the use of the substrate holder, and
the updating step is a step performed at a timing to end the use of the substrate holder.

13. The managing method according to claim 11, wherein the plating apparatus includes a first processing lane and a second processing lane,
the use attribute includes attributes indicating “an unused state”, “a state of being used in the first processing lane”, “a state of being used in the second processing lane”, and “a maintenance waiting state”,
the managing method comprising: permitting the substrate holder having the use attribute indicating “the unused state” to be used in the first processing lane or the second processing lane, permitting the substrate holder having the use attribute indicating “the state of being used in the first processing lane” to be used in the first processing lane, permitting the substrate holder having the use attribute indicating “the state of being used in the second processing lane” to be used in the second processing lane, and prohibits the substrate holder having the use attribute indicating “the maintenance waiting state” from being used in the first processing lane and the second processing lane.
